(19) United States
(12) Patent Application Publication
(10) Pub. No.: US 2024/0306398 A1
(43) Pub. Date: Sep. 12, 2024

(54) THREE DIMENSIONAL NON-VOLATILE MEMORY DEVICE

(71) Applicant: Samsung Electronics Co., Ltd., Suwon-si (KR)

(72) Inventors: Yongseok KIM, Suwon-si (KR); Yukio HAYAKAWA, Suwon-si (KR); Minjun LEE, Suwon-si (KR); Bongyong LEE, Suwon-si (KR); Siyeon CHO, Suwon-si (KR)

(73) Assignee: Samsung Electronics Co., Ltd., Suwon-si (KR)

(21) Appl. No.: 18/594,350

(22) Filed: Mar. 4, 2024

(30) Foreign Application Priority Data
Mar. 7, 2023 (KR) 10-2023-0030202

(51) Int. Cl. H10B 53/30; H10B 53/20

(52) U.S. Cl. CPC H10B 53/30; H10B 53/20

(57) ABSTRACT

A three-dimensional non-volatile memory device includes a plurality of horizontal word lines spaced apart from each other in a vertical direction, a pillar gate electrode buried in a first channel hole that passes through the horizontal word lines in the vertical direction, and a first dielectric layer disposed between the pillar gate electrode and the horizontal word lines in a cross section. The pillar gate electrode, the first dielectric layer, and the horizontal word lines correspond to memory cells including a plurality of variable capacitors spaced apart from each other in a vertical direction. The memory device further includes a selection transistor on the pillar gate electrode and the horizontal word lines and connected to one end of the pillar gate electrode, and a storage transistor under the pillar gate electrode and the horizontal word lines and connected to another end of the pillar gate electrode.

### CROSS-REFERENCE TO RELATED APPLICATION

This application is based on and claims priority under 35 U.S.C. § 119 to Korean Patent Application No. 10-2023-0030202, filed on Mar. 7, 2023, in the Korean Intellectual Property Office, the disclosure of which is incorporated by reference herein in its entirety.

### BACKGROUND

Various example embodiments to a memory device, and more particularly, to a three dimensional non-volatile memory device including a plurality of cells (or memory cells) repeatedly arranged in three dimensions.

To improve the degree of integration of a nonvolatile memory device, cell transistors may be vertically stacked to improve the degree of integration. In particular, in the case of a NAND flash memory device among non-volatile memory devices, since one cell (or memory cell) is composed of one transistor (1T), the degree of integration may be improved by vertically stacking the cell transistors. However, in the case of a three dimensional non-volatile memory device in which cell transistors included in the nonvolatile memory device are vertically stacked, it is necessary or desirable to improve the endurance characteristics of each cell transistor positioned in the vertical direction.

### SUMMARY

Various example embodiments provide a three dimensional non-volatile memory device capable of improving endurance characteristics of individual memory cells positioned in a vertical direction.

According to some example embodiments, there is provided a three dimensional non-volatile memory device including a plurality of horizontal word lines spaced apart from each other in a vertical direction, a pillar gate electrode buried in a first channel hole that penetrates the horizontal word lines in the vertical direction, a first dielectric layer between the pillar gate electrode and the horizontal word lines in cross section. The pillar gate electrode, the first dielectric layer, and the horizontal word lines correspond to memory cells including a plurality of variable capacitors spaced apart from each other in a vertical direction. The memory device further includes a selection transistor on the pillar gate electrode and the horizontal word lines and connected to one end of the pillar gate electrode, and a storage transistor under the pillar gate electrode and the horizontal word lines and connected to another end of the pillar gate electrode.

Alternatively or additionally according to various example embodiments, there is provided a three dimensional non-volatile memory device including a plurality of horizontal word lines spaced apart from each other in a vertical direction, a pillar gate electrode buried in a first channel hole that penetrates the horizontal word lines in the vertical direction, and a first dielectric layer between the pillar gate electrode and the horizontal word lines in cross section. The pillar gate electrode, the first dielectric layer, and the horizontal word lines correspond to memory cells including a plurality of variable capacitors spaced apart from each other in a vertical direction, a string selection line spaced apart from an uppermost horizontal word line among the horizontal word lines in the vertical direction. The memory device further includes a channel layer buried in a second channel hole penetrating the string selection line in the vertical direction and connected to one end of the pillar gate electrode, a second dielectric layer between the channel layer and the string selection line, and a storage transistor connected to another end of the pillar gate electrode.

Alternatively or additionally according to various example embodiments, there is provided a three dimensional non-volatile memory device including a plurality of horizontal word lines spaced apart from each other in a vertical direction, a pillar gate electrode buried in a first channel hole that penetrates the horizontal word lines in the vertical direction, and a first dielectric layer between the pillar gate electrode and the horizontal word lines in cross section, wherein the pillar gate electrode, the first dielectric layer, and the horizontal word lines correspond to memory cells including a plurality of variable capacitors spaced apart from each other in a vertical direction. The memory device further includes a selection transistor on the pillar gate electrode and the horizontal word lines and connected to one end of the pillar gate electrode, wherein the selection transistor includes a string selection line spaced apart from an uppermost horizontal word line among the horizontal word lines in the vertical direction, a channel layer connected to one end of the pillar gate electrode, and a second dielectric layer between the channel layer and the string selection line, a storage transistor below the pillar gate electrode and the horizontal word lines and connected to another end of the pillar gate electrode, and a control transistor below the pillar gate electrode and the horizontal word lines and connected to the storage transistor.

### BRIEF DESCRIPTION OF THE DRAWINGS

Various example embodiments will be more clearly understood from the following detailed description taken in conjunction with the accompanying drawings in which:

FIG. 1 is a plan view of a three-dimensional non-volatile memory device according to some example embodiments;

FIG. 2 is a cross-sectional view of a unit cell of a three-dimensional non-volatile memory device according to some example embodiments;

FIG. 3 is a cross-sectional view of a main part of FIG. 2;

FIG. 4 is a perspective view of the main part of FIG. 2;

FIG. 5A is a two-dimensional circuit diagram of a unit cell of a three dimensional non-volatile memory device according to some example embodiments;

FIG. 5B is a three-dimensional circuit diagram of a three-dimensional non-volatile memory device according to some example embodiments;

FIG. 5C is a diagram illustrating a capacitance change according to application of a voltage to each of the memory cells of FIG. 5A;

FIGS. 6 and 8 are circuit diagrams for explaining the operation of a unit cell of a three-dimensional non-volatile memory device according to some example embodiments;

FIG. 9 is a cross-sectional view of a unit cell of a three-dimensional non-volatile memory device according to some example embodiments;

FIG. 10 is a circuit diagram for explaining the operation of a unit cell of a three-dimensional non-volatile memory device according to some example embodiments;

FIG. 11 is a circuit diagram for explaining the operation of a unit cell of a three-dimensional non-volatile memory device according to some example embodiments;

FIGS. 12 to 19 are cross-sectional views illustrating a method of manufacturing a unit cell of a three-dimensional non-volatile memory device according to some example embodiments; and

FIGS. 20 to 26 are cross-sectional views illustrating a method of manufacturing a unit cell of a three-dimensional non-volatile memory device according to some example embodiments.

### DETAILED DESCRIPTION OF VARIOUS EXAMPLE EMBODIMENTS

Hereinafter, some example embodiments will be described in detail with reference to the accompanying drawings. The following embodiments may be implemented by only one, and in addition, the following example embodiments may be implemented by combining one or more. Therefore, the technical idea of inventive concepts are not limited to one embodiment and is not interpreted thereto.

As used herein, the singular form of the constituent elements may include a plurality of forms unless the context clearly indicates a different case. As used herein, drawings are or may be exaggerated to more clearly describe inventive concepts.

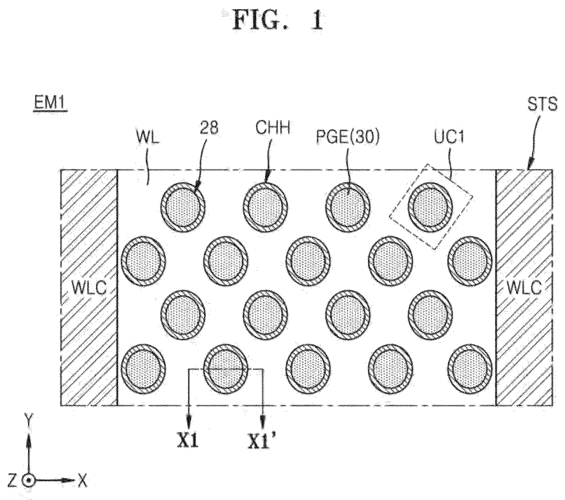

FIG. 1 is a plan view of a three dimensional non-volatile memory device according to various example embodiments.

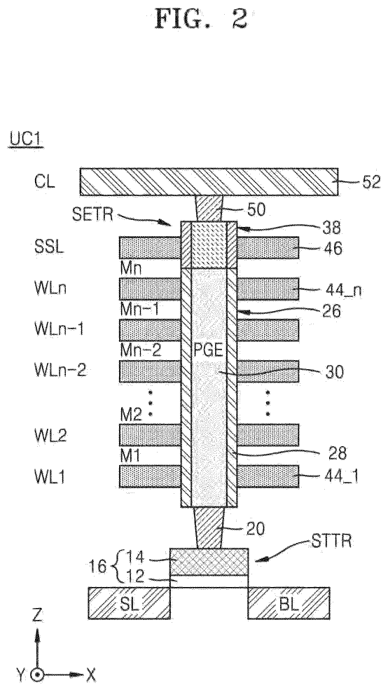

FIG. 1 may be a plan view of memory cells M1 to Mn in FIG. 2 (where n is a positive integer) of a three dimensional non-volatile memory device EM1. The three dimensional non-volatile memory device EM1 may include a stacked body STS. The stacked body STS may be formed on a horizontal plane (X-Y plane). Although FIG. 1 shows only one stacked body STS for convenience, a plurality of stacked bodies STS formed on a substrate and positioned apart from each other may be provided.

The stacked body STS may include a horizontal word line WL and word line cuts WLC. As will be described later, the horizontal word lines WL may be spaced apart from each other in a vertical direction (Z direction). Word line cuts WLC may be formed on both sides of the horizontal word line WL. Channel holes CHH and/or word line cuts WLC may be holes penetrating upper and lower surfaces of the stacked body STS. The horizontal word line WL may extend in a second horizontal direction (Y direction) and be cut in a first horizontal direction (X direction).

The plurality of channel holes CHH may be disposed in the horizontal word line WL between the word line cuts WLC of the stacked body STS. In FIG. 1, it is illustrated that five channel holes CHH are disposed between the word line cuts WLC with respect to the first horizontal direction (X direction), but the number of channel holes CHH disposed between the word line cuts WLC is not limited thereto. For example, four or fewer channel holes CHH may be disposed between the word line cuts WLC, or six or more channel holes CHH may be disposed between the word line cuts WLC. Additionally or alternatively, the channel holes CHH may be arranged as a lattice, such as at points in a triangular (e.g., equilateral) lattice; however, example embodiments are not limited thereto. Additionally or alternatively, the channel holes are illustrated as being circular; however, example embodiments are not limited thereto.

Cell transistors M1 to Mn in FIG. 2 (where n is a positive integer) of a three dimensional non-volatile memory device EM1 may be formed in the channel holes CHH, as will be described later. The memory cells M1 to Mn in FIG. 2 formed in each of the channel holes CHH may constitute or correspond to a unit cell UC1. The memory cells M1 to Mn may be described as cell transistors; however, as shown in more detail below the memory cells M1 to Mn may be programmed as variable capacitor memory cells. A pillar gate electrode PGE 30 and a first dielectric layer 28 may be disposed in each of the channel holes CHH of the unit cell UC1.

A first dielectric layer 28 may be disposed between the pillar gate electrodes PGE 30 and the horizontal word line WL. The first dielectric layer 28 may surround the pillar gate electrodes PGE 30. The first dielectric layer 28 may be positioned on inner walls of each of the channel holes CHH. The first dielectric layer 28 may be composed of or may include at least one of a ferroelectric layer or an antiferroelectric layer. The pillar gate electrodes PGE 30, the first dielectric layer 28, and the horizontal word line WL may constitute a variable capacitor. For example, in some example embodiments the pillar gate electrode PGE 30 may be one plate of the variable capacitor, the horizontal word line WL may be another plate of the variable capacitor, and the first dielectric layer 28 may be the dielectric layer therebetween. The variable capacitor may be a coaxial capacitor; however, example embodiments are not limited thereto.

The three dimensional non-volatile memory device EM1 configured as described above includes variable capacitors between the pillar gate electrode PGE 30 and the horizontal word line WL in each cell transistor of the unit cell UC1, such that endurance characteristics of cell transistors may be improved. This will be explained in more detail later.

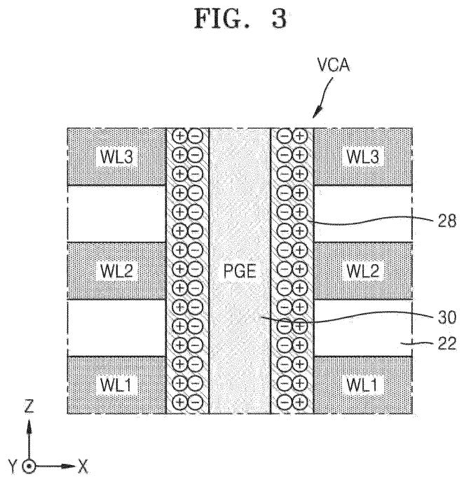

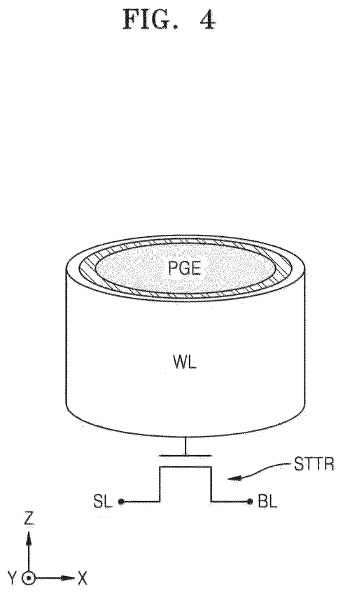

FIG. 2 is a cross-sectional view of a unit cell of a three dimensional non-volatile memory device according to some example embodiments of technical ideas of inventive concepts, and FIG. 3 is a cross-sectional view of a main part of FIG. 2, and FIG. 4 is a perspective view of a main part of FIG. 2.

Specifically, FIG. 2 may include a cross-sectional view of a main part of a unit cell UC1 in FIG. 1 of a three dimensional non-volatile memory device EM1 in FIG. 1. FIG. 2 may include a cross-sectional view of main parts taken along line X1-X1′ of FIG. 1. FIG. 3 is a cross-sectional view of some of the cell transistors M1 to Mn (where n is a positive integer) of FIG. 2, and FIG. 4 is a perspective view of a lowermost horizontal word line WL1 among a plurality of horizontal word lines WL1 to WLn (where n is a positive integer) of FIG. 2.

The unit cell UC1 of the three dimensional non-volatile memory device EM1 in FIG. 1 may include a storage transistor STTR, a plurality of cell transistors M1 to Mn, and a selection transistor SETR. Hereinafter, the unit cell UC1 of the three dimensional non-volatile memory device EM1 in FIG. 1 will be mainly described.

The cell transistors M1 to Mn may include horizontal word lines WL1 to WLn and 44_1 to 44_n (where n is a positive integer), pillar gate electrodes PGE 30, and a first dielectric layer 28. The horizontal word lines WL1 to WLn and 44_1 to 44_n may be spaced apart from each other in a vertical direction (Z direction).

The horizontal word lines WL1 to WLn may be insulated by the lower insulating layer 22 as shown in FIG. 3. The pillar gate electrodes PGE 30 may be disposed in the first channel hole 26 penetrating the horizontal word lines WL1 to WLn and 44_1 to 44_n in a vertical direction (Z direction). The first channel hole 26 may correspond to the channel hole CHH of FIG. 1.

The pillar gate electrodes PGE 30 may be made of metal, conductive metal nitride, conductive semiconductor material, or a combination thereof. In some example embodiments, the pillar gate electrode PGE 30 may be formed of W, Al, Cu, Co, Mo, Ti, Ta, TiN, TaN, WN, WCN, TiSiN, TaSiN, WSiN, or a combination thereof, but is not limited thereto.

The first dielectric layer 28 may be disposed to surround the pillar gate electrodes PGE 30. The first dielectric layer 28 may be positioned on first and second (or both) sides of the pillar gate electrodes PGE 30 in cross section. The first dielectric layer 28 may be positioned between the pillar gate electrode PGE 30 and the horizontal word lines WL1 to WLn and 44_1 to 44_n.

The first dielectric layer 28 may include a ferroelectric layer or an antiferroelectric layer. In some example embodiments, the ferroelectric layer may include at least one oxide selected from the group consisting of or including Hf, Si, Al, Zr, Y, La, Gd, and Sr. For example, the ferroelectric layer may include a hafnium-based oxide, such as hafnium oxide (HfO), hafnium zirconium oxide (HZO), hafnium titanium oxide, or hafnium silicon oxide. The ferroelectric layer may further include a dopant as needed. The dopant may consist of or include at least one element selected from Si, Al, Zr, Y, La, Gd, Sc, Sr, Mg, and Ba, but is not limited thereto.

As shown in FIG. 3, a variable capacitor VCA may be formed by the first dielectric layer 28 between the pillar gate electrode PGE 30 and the horizontal word lines WL1 to WLn and 44_1 to 44_n. When the first dielectric layer 28 is ferroelectric, the variable capacitor VCA may be or correspond to a ferroelectric variable capacitor. When the first dielectric layer 28 is antiferroelectric, the variable capacitor VCA may be or correspond to an antiferroelectric variable capacitor.

Due to a difference in via voltage between the pillar gate electrode PGE 30 and the horizontal word lines WL1 to WLn, electrical polarization of the first dielectric layer 28 is changed so that data may be programmed into the cell transistors M1 to Mn or data may be deleted.

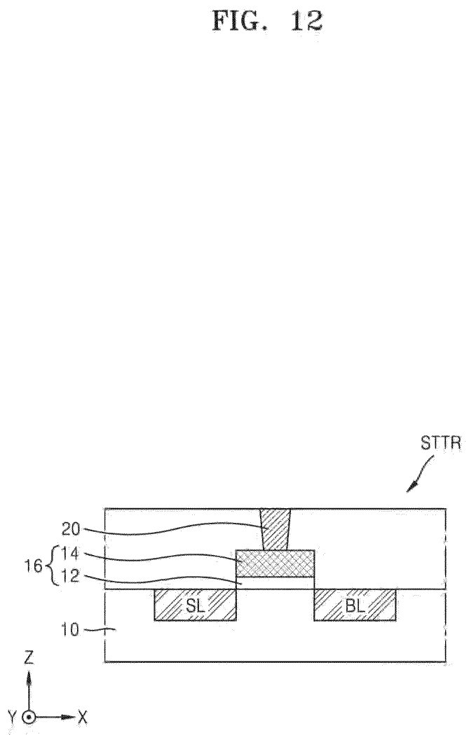

The storage transistor STTR may include a gate 16 formed on a substrate 10 in FIG. 12, a source line SL, and a bit line BL. Although the storage transistor STTR is illustrated as being a planar NMOS transistor, example embodiments are not limited thereto. The pillar gate electrode 30 constituting or included in the cell transistors M1 to Mn may be connected to the storage transistor STTR.

One end of the pillar gate electrode 30 constituting the cell transistors M1 to Mn may be connected to the gate 16 through the first plug 20. The gate 16 may include a gate insulating layer 12 and a gate electrode 14. In some example embodiments, the gate insulating layer 12 may consist of or correspond to only one layer, such as a silicon oxide layer.

The source line SL and the bit line BL may correspond to a source region and a drain region, respectively. Data stored in the cell transistors M1 to Mn may be read by floating the pillar gate electrode PGE 30 and detecting a current flowing through the storage transistor STTR.

The selection transistor SETR may include a string selection line SSL, a second dielectric layer 40, and a channel layer 42. The string selection line SSL may extend in a first horizontal direction, for example, in an X direction. A second channel hole 38 may be disposed in a vertical direction within the string selection line SSL. The second channel hole 38 may communicate with the first channel hole 26.

A second dielectric layer 40 and a channel layer 42 may be formed in the second channel hole 38. The channel layer 42 may be buried in the second channel hole 38 on the second dielectric layer 40. In some example embodiments, the second dielectric layer 40 may be formed of a silicon oxide film, a high-k film, or a combination thereof. The high-k film may be or may be made of a material having a higher dielectric constant than the silicon oxide film.

The channel layer 42 may extend in a vertical direction (Z direction). The channel layer 42 may be connected to the other end of the pillar gate electrode 30 constituting the cell transistors M1 to Mn. The channel layer 42 may be an active region. In some example embodiments, the channel layer 42 may be made of undoped polysilicon, doped polysilicon, a compound semiconductor material, an oxide semiconductor material, a two-dimensional semiconductor material, or a combination thereof. The string selection line SSL may turn the selection transistor SETR on or off to select the cell transistors M1 to Mn.

The selection transistor SETR may be connected to the control line CL. The control line CL may be connected to the channel layer 42 of the selection transistor SETR through the second plug 50. The control line CL may apply a program voltage for programming data or an erase voltage for removing data to the cell transistors M1 to Mn.

In the unit cell UC1 of the above three dimensional non-volatile memory device EM1 in FIG. 1, the cell transistors M1 to Mn do not have a channel layer or an interface layer, and variable capacitors VCA are provided between the pillar gate electrode PGE 30 and the horizontal word lines WL1 to WLn and 44_1 to 44_n.

Accordingly, the unit cell UC1 of the three dimensional non-volatile memory device EM1 in FIG. 1 of inventive concepts does not include a channel layer (or interface layer) in the cell transistors M1 to Mn, such that deterioration of durability characteristics of the cell transistors M1 to Mn due to charges injected into the channel layer may be prevented or reduced in likelihood of occurrence and/or of impact from occurrence.

For example, the unit cell UC1 of the three dimensional non-volatile memory device EM1 in FIG. 1 includes variable capacitors VCA between cell transistors M1 to Mn and horizontal word lines WL1 to WLn in the cell transistors M1 to Mn, such that endurance characteristics of the cell transistors M1 to Mn may be improved. The memory device may be or may include a one variable-capacitor (1VC) device.

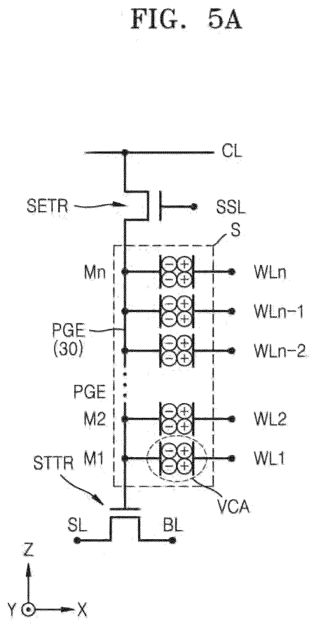

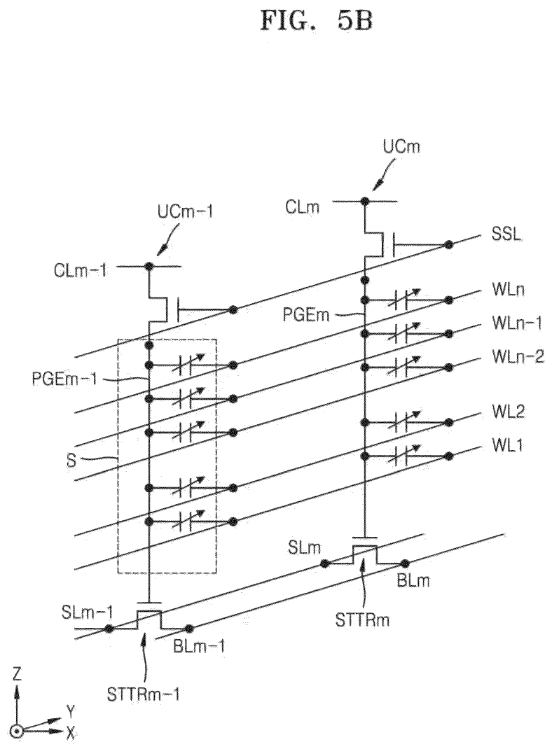

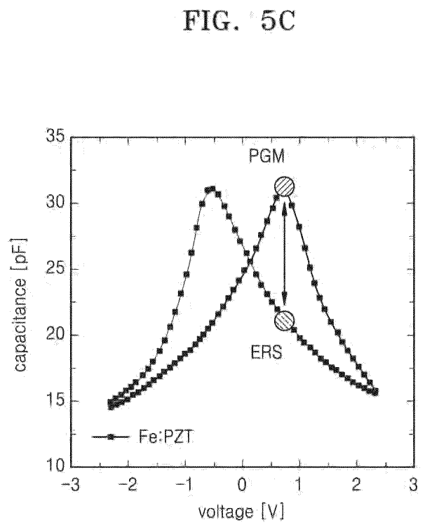

FIG. 5A is a two-dimensional circuit diagram of a unit cell of a three dimensional non-volatile memory device according to some example embodiments of technical ideas of inventive concepts, FIG. 5B is a three-dimensional circuit diagram of a three dimensional non-volatile memory device according to some example embodiments of technical idea of inventive concepts, and FIG. 5C is a diagram illustrating a capacitance change according to application of a voltage to each of the cell transistors of FIG. 5A.

Specifically, FIG. 5A may be a two dimensional circuit diagram of a unit cell UC1 of a three dimensional non-volatile memory device EM1 in FIG. 1. FIG. 5B may be a three-dimensional circuit diagram of a three dimensional non-volatile memory device EM1 in FIG. 1.

As shown in FIG. 5A, the unit cell UC1 of the three dimensional non-volatile memory device EM1 in FIG. 1 is two-dimensionally connected with n cell transistors M1 to Mn in series to form a cell string S.

As shown in FIG. 5B, the three dimensional non-volatile memory device EM1 in FIG. 1, the cell strings S are connected in parallel between the control lines CLm and CLm-1 and the gates of the storage transistors STTRm and STTRm-1. FIG. 5B shows two unit cells UClm-1 and UClm for convenience. In FIG. 5B, reference numeral SL denotes a source line, reference numeral BL denotes a bit line, and reference numerals PGEm-1 and PGEm denote pillar gate electrodes.

The unit cell UC1 of the three dimensional non-volatile memory device EM1 in FIG. 1, as shown in FIG. 5A, may include a cell string S in which cell transistors M1 to Mn are connected in series, a selection transistor SETR for selecting the cell string S, and horizontal word lines WL1 to WLn which are means for selecting the cell transistors M1 to Mn. The selection transistor SETR may include a string selection line SSL.

The cell transistors M1 to Mn may include variable capacitors VCA between the pillar gate electrodes PGE 30 and the horizontal word lines WL1 to WLn. The variable capacitors VCA may be spaced apart from each other in a vertical direction (Z direction).

As shown in FIG. 5C, the capacitance of each variable capacitor VCA may be changed by changing the electric polarization of the first dielectric layer 28 of FIG. 2 in a manner depending on the voltage applied to the pillar gate electrode 30 through the control line CL or the voltage applied to the horizontal word lines WL1 to WLn.

As shown in FIG. 5C, the program capacitance value PGM and the erase capacitance value ERS may be different according to the electrical polarization of the first dielectric layer 28 in FIGS. 2 and 3. Example embodiments, e.g., as illustrated in FIG. 5C shows a program capacitance value PGM and an erase capacitance value ERS when PZT containing iron Fe is used for the first dielectric layer 28 in FIGS. 2 and 3.

The unit cell UC1 of the three dimensional non-volatile memory device EM1 in FIG. 1 may include a string selection line SSL connected to one side of the cell string S and composed of a selection transistor SETR, a control line CL connected to the selection transistor SETR, and a storage transistor STTR connected to the other side of the cell string S. The selection transistor SETR may be named a string selection transistor. The storage transistor STTR may include a gate 16 in FIG. 2, a source line SL, and a bit line BL.

In one cell string S, 2m (m is a natural number greater than or equal to 1 that may be greater than, less than, or equal to n) cell transistors M1 to Mn may be formed. About two, four, eight, or sixteen cell transistors M1 to Mn may be connected in series to one cell string S.

Referring to FIGS. 5A and 5B, the first horizontal direction (X direction) may be a direction in which the control line CL extends. The second horizontal direction (Y direction) may be a direction in which the horizontal word lines WL1 to WLn extend. The vertical direction (Z direction) may be a direction perpendicular to the horizontal word lines WL1 to WLn and the control line CL.

The horizontal word lines WL1 to WLn, the string selection line SSL, and the control line CL may be made of metal, a conductive metal nitride, a conductive semiconductor material, or a combination thereof. In some embodiments, the horizontal word lines WL1 to WLn, the string selection line SSL, and the control line (CL) may be formed of W, Al, Cu, Co, Mo, Ti, Ta, TiN, TaN, WN, WCN, TiSiN, TaSiN, WSiN, or a combination thereof, but are not limited thereto.

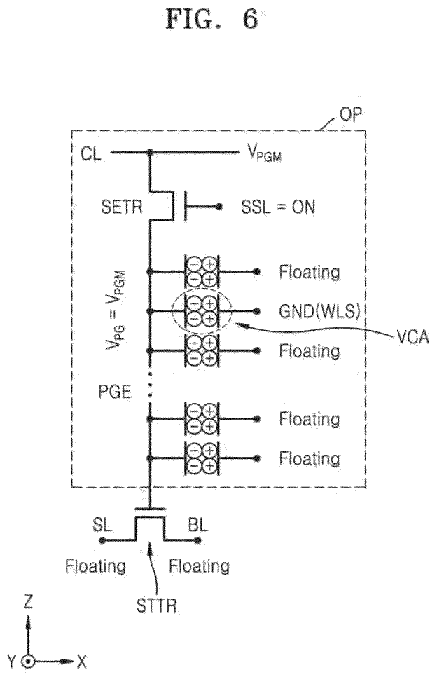

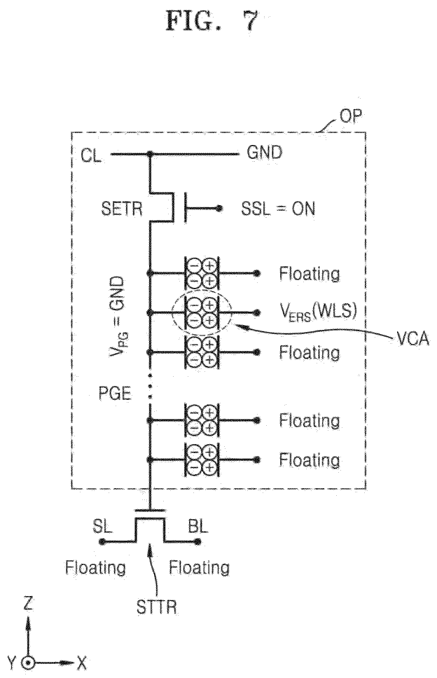

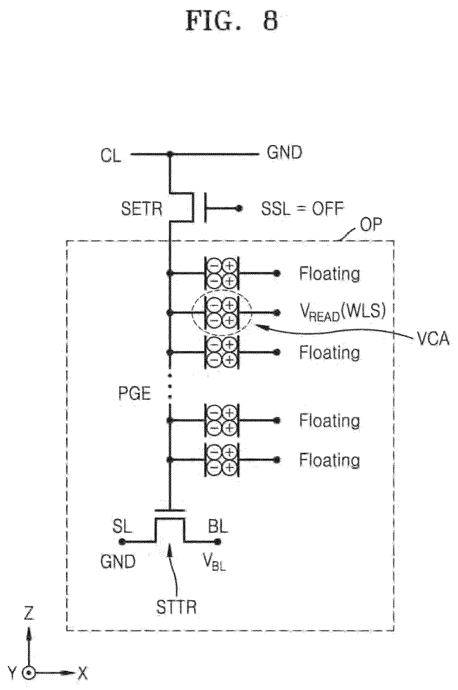

FIGS. 6 and 8 are circuit diagrams for explaining the operation of a unit cell of a three dimensional non-volatile memory device according to some example embodiments of technical ideas of inventive concepts.

Specifically, FIGS. 6 to 8 are circuit diagrams for explaining operations using a two-dimensional circuit diagram of a unit cell UC1 in FIG. 5A of a three dimensional non-volatile memory device EM1 in FIG. 1. FIG. 6 is for explaining a program operation of the unit cell UC1 in FIG. 5A. FIG. 7 is for explaining an erase operation of the unit cell UC1 in FIG. 5A, and FIG. 6 is for explaining a read operation for the unit cell UC1 in FIG. 5A. In relation to FIGS. 6 to 8, the contents described with reference to FIGS. 5A to 5C are briefly described or omitted.

As shown in FIG. 6, the program voltage VPGM is applied to the control line CL, and the string voltage is applied to the string selection line SSL to turn on the selection transistor SETR, such that the program voltage VPGM is applied to the pillar gate electrode PGE. The pillar gate voltage VPG of the pillar gate electrode PGE may be equal to the program voltage VPGM.

The selected horizontal word line WLS from among the horizontal word lines WL1 to WLn in FIG. 5A applies the ground voltage GND, and allows the remaining horizontal word lines WL1 to WLn in FIG. 5A to float or be electrically disconnected or placed into a high-impedance state. The source line SL and the bit line BL of the storage transistor STTR are floated or electrically disconnected or placed into a high-impedance state. In this case, a variable capacitor VCA may be formed between the pillar gate electrode and the selected horizontal word line WLS, and a current may flow from the control line CL to the selected horizontal word line WLS.

The variable capacitor VCA may indicate a program capacitance value PGM as shown in FIG. 5C according to the electric polarization of the first dielectric layer 28 in FIG. 2, and accordingly, the program operation of the unit cell UC1 in FIG. 5A may be performed. As shown in FIG. 6, the part OP performing the program operation does not affect the storage transistor STTR. Accordingly, durability of the unit cell UC1 in FIG. 5A may be improved without affecting the gate insulating layer 12 in FIG. 2 constituting the storage transistor STTR.

As shown in FIG. 7, the ground voltage GND is applied to the control line CL, and the string voltage is applied to the string selection line SSL to turn on the selection transistor SETR, such that the ground voltage GND is applied to the pillar gate electrode PGE. The pillar gate voltage VPG of the pillar gate electrode PGE may be equal to the ground voltage GND.

The selected horizontal word line WLS from among the horizontal word lines WL1 to WLn in FIG. 5A applies the erase voltage VERS, and blocks the remaining horizontal word lines WL1 to WLn in FIG. 5A. The source line SL and the bit line BL of the storage transistor STTR are floated. In this case, the variable capacitor VCA may be formed between the pillar gate electrode PGE and the selected horizontal word line WLS, and a current may flow from the selected horizontal word line WLS to the control line CL.

The variable capacitor VCA may indicate an erase capacitance value ERS as shown in FIG. 5C according to the electric polarization of the first dielectric layer 28 in FIG. 2, and accordingly, the erase operation of the unit cell UC1 in FIG. 5A may be performed. As shown in FIG. 7, the part OP performing the erase operation does not affect the storage transistor STTR. Accordingly, durability of the unit cell UC1 in FIG. 5A may be improved without affecting the gate insulating layer 12 in FIG. 2 constituting or included in the storage transistor STTR.

As shown in FIG. 8, the selection transistor SETR is turned off by applying the ground voltage GND to the control line CL and applying the string off voltage to the string selection line SSL.

The selected horizontal word line WLS from among the horizontal word lines WL1 to WLn in FIG. 5A applies the read voltage VREAD, and allows the remaining horizontal word lines WL1 to WLn in FIG. 5A to float. Also, the bit line voltage VBL is applied to the bit line BL of the storage transistor STTR. In this case, current may flow between the selected horizontal word line WLS and the bit line BL of the storage transistor STTR through the variable capacitor VCA. A read operation of the unit cell may be performed by detecting a current flowing through the storage transistor STTR. As shown in FIG. 7, only the part OP performing the read operation may affect the storage transistor STTR.

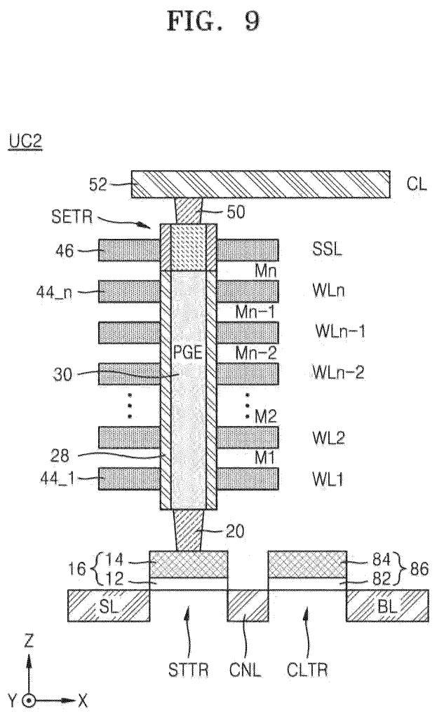

FIG. 9 is a cross-sectional view of a unit cell of a three dimensional non-volatile memory device according to some example embodiments.

Specifically, the unit cell UC2 of the three dimensional non-volatile memory device EM1 in FIG. 1 shown in FIG. 9 may be identical to the unit cell UC1 of FIGS. 2 to 4 except for further including a control transistor CLTR. In FIG. 9, the contents described with reference to FIGS. 2 to 4 are briefly described or omitted.

The unit cell UC2 of the three dimensional non-volatile memory device EM1 in FIG. 1 may include a storage transistor STTR, a plurality of cell transistors M1 to Mn, a selection transistor SETR, and a control transistor CLTR.

The storage transistor STTR may include a gate 16 formed on a substrate 10 in FIG. 12, a source line SL, and a connection line CNL. The gate 16 may include a gate insulating layer 12 and a gate electrode 14. In some embodiments, the gate insulating layer 12 may consist of one layer, such as a single silicon oxide layer. The gate insulating layer 12, the gate electrode 14, and the gate may be referred to as a first gate insulating layer, a first gate electrode, and a first gate, respectively. The pillar gate electrode 30 constituting the cell transistors M1 to Mn may be connected to the storage transistor STTR and the gate 16.

The control transistor CLTR may be connected to the storage transistor STTR in a first horizontal direction (X direction). The control transistor CLTR may include a connection line CNL, a second gate 86 and a bit line BL. The connection line CNL may be shared with the storage transistor STTR. The second gate 86 may include a second gate insulating layer 82 and a second gate electrode 84. In some example embodiments, the second gate insulating layer 82 may include a silicon oxide layer.

The control transistor CLTR and the storage transistor STTR may have the same, or different electrical properties. The control transistor CLTR and the storage transistor STTR may have the same, or different, physical properties.

The source line SL, connection line CNL, and bit line BL may respectively correspond to a source region, a connection region, and a drain region. The data of the cell transistors M1 to Mn may be easily read by floating the pillar gate electrode PGE 30 and detecting the current flowing through the storage transistor STTR and control transistor CLTR.

As described above, the unit cell UC2 of the three dimensional non-volatile memory device EM1 in FIG. 1 shown in FIG. 9 further includes a control transistor CLTR to easily read data stored in the cell transistors M1 to Mn.

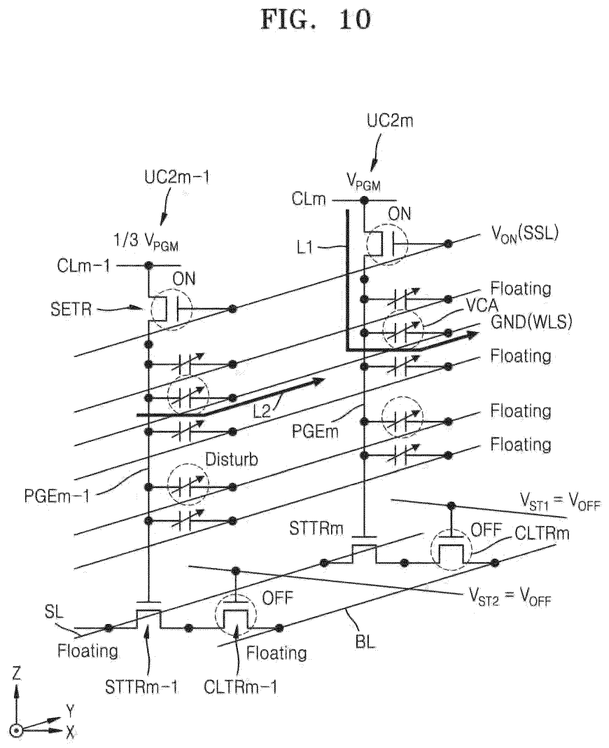

FIG. 10 is a circuit diagram for explaining the operation of a unit cell of a three dimensional non-volatile memory device according to some example embodiments of technical ideas of inventive concepts.

Specifically, FIG. 9 and FIG. 10 are for explaining a program operation using a three-dimensional circuit diagram of a unit cell UC2 of a three dimensional non-volatile memory device EM1 in FIG. 1. In FIG. 10, the contents described with reference to FIGS. 5A to 5C and FIG. 9 are briefly described or omitted.

FIG. 10 shows two unit cells UC2m-1 and UC2m for convenience. In FIG. 10, reference numerals PGEm-1 and PGEm denote pillar gate electrodes, reference numerals STTRm and STTRm-1 denote storage transistors, and reference numerals CLTRm and CLTRm-1 denote control transistors.

As shown in FIG. 10, the program voltage VPGM is applied to the control line CLm in the unit cell UC2m, and the string voltage VON is applied to the string selection line SSL to turn on the selection transistor SETR, such that the program voltage VPGM is applied to the pillar gate electrode PGEm. The pillar gate voltage VPG of the pillar gate electrode PGEm may be equal to the program voltage VPGM.

The selected horizontal word line WLS from among the horizontal word lines WL1 to WLn in FIG. 5A applies the ground voltage GND, and allows the remaining horizontal word lines WL1 to WLn in FIG. 5A to float. In this case, a variable capacitor VCA may be formed between the pillar gate electrode PGEm and the selected horizontal word line WLS, and as indicated by reference numeral L1, current may flow from the control line CLm to the selected horizontal word line WLS. The variable capacitor VCA may indicate a program capacitance value PGM as shown in FIG. 5C according to the electric polarization of the first dielectric layer 28 in FIG. 2, and accordingly, the program operation of the unit cell UC2 in FIG. 10 may be performed.

In addition, as shown in FIG. 10, according to the floating potentials of unselected horizontal word lines among the horizontal word lines WL1 to WLn in FIG. 5A, as shown in line L2, program disturbance may occur. Accordingly, when the ⅓ program voltage VPGM is applied to the control line CLm-1 in the unit cell UC2m-1, program confusion may be reduced.

Also, during a program operation of the unit cell UC2, the source lines SL of the storage transistors STTRm-1 and STTRm are floated, and the bit lines BL of the control transistors CLTRm-1 and CLTRm are floated. During program operation of unit cell UC2, an off voltage VOFF is applied to the second control gate line VST2 of the control transistor CLTRm-1 and the first control gate line VST2 of the control transistor CLTRm to turn off the control transistors CLTRm-1 and CLTRm.

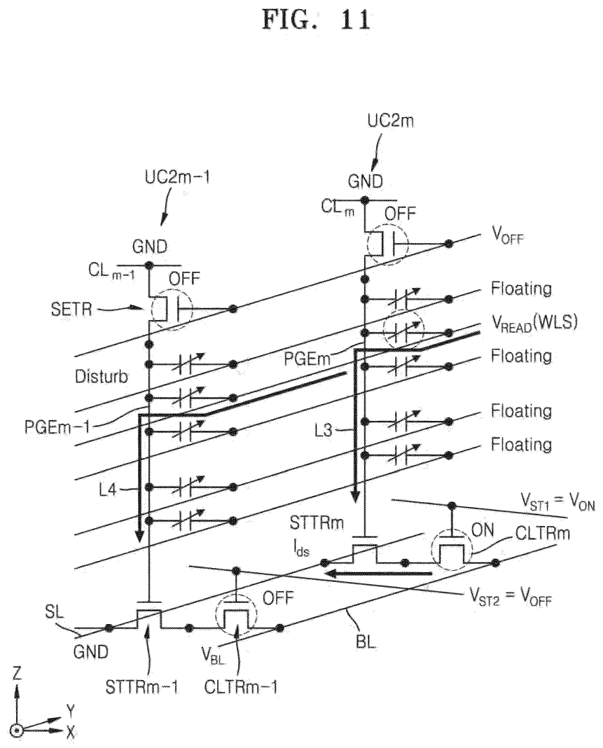

FIG. 11 is a circuit diagram for explaining the operation of a unit cell of a three dimensional non-volatile memory device according to some example embodiments of technical ideas of inventive concepts.

Specifically, FIG. 11 and FIG. 9 are for explaining a read operation using a three-dimensional circuit diagram of a unit cell UC2 of a three dimensional non-volatile memory device EM1 in FIG. 1. In FIG. 11, the contents described with reference to FIGS. 5A to 5C and FIG. 9 are briefly described or omitted.

FIG. 11 shows two unit cells UC2m-1 and UC2m for convenience. In FIG. 11, reference numerals PGEm-1 and PGEm denote pillar gate electrodes, reference numerals STTRm and STTRm-1 denote storage transistors, and reference numerals CLTRm and CLTRm-1 denote control transistors.

As shown in FIG. 11, the ground voltage GND is applied to the control lines CLm and CLm-1 in the unit cell UC2m, and the string off voltage VOFF is applied to the string selection line SSL to turn off the selection transistor SETR.

The selected horizontal word line WLS from among the horizontal word lines WL1 to WLn in FIG. 5A applies the read voltage VREAD, and allows the remaining unselected horizontal word lines WL1 to WLn in FIG. 5A to float. Then, the bit line voltage VBL is applied to the bit lines BL of the storage transistors STTRm and STTRm-1. In this case, current may flow between the selected horizontal word line WLS and the bit line BL of the storage transistor STTR through the variable capacitor VCA as indicated by reference sign L3. A read operation of the unit cell UC2m may be performed by detecting a current flowing through the storage transistor STTRm.

During a read operation of the unit cell UC2m, the source lines SL of the storage transistors STTRm-1 and STTRm are grounded, and the bit line BL of the control transistors CLTRm-1 and CLTRm applies the bit line voltage VBL. During a read operation of the unit cell UC2m, the second control gate line VST2 of the control transistor CLTRm-1 applies an off voltage VOFF to turn off the control transistor CLTRm-1. During a read operation of the unit cell UC2m, the first control gate line VST1 of the control transistor CLTRm applies the turn-on voltage VON to turn the control transistor CLTRm on.

In addition, as shown in FIG. 11, according to the floating potentials of unselected horizontal word lines among the horizontal word lines WL1 to WLn in FIG. 5A, as shown in line L4, program disturbance may occur. However, by turning off the control transistor CLTRm-1 in the unit cell UC2m-1, the current flow of the selected storage transistor flows to the source line SL as shown by reference numeral L4 to reduce program confusion.

FIGS. 12 to 19 are cross-sectional views illustrating a method of manufacturing a unit cell of a three dimensional non-volatile memory device according to some example embodiments.

Specifically, FIGS. 12 to 19 are for explaining some example embodiments of a method of manufacturing the unit cell UC1 of the three dimensional non-volatile memory device EM1 of FIG. 1 of FIGS. 2 to 4. In FIGS. 12 to 19, the same members as those in FIGS. 2 to 4 are denoted by the same reference numerals, and the same details are briefly described or omitted.

Referring to FIG. 12, a storage transistor STTR is formed on the substrate 10. The storage transistor STTR may include a source line SL and a bit line BL formed apart from each other on the substrate 10. The source line SL and the bit line BL may be a source region and a drain region respectively formed on the substrate 10. The storage transistor STTR may be a planar transistor; however, example embodiments are not limited thereto.

A gate 16 is formed on the substrate 10 between the source line SL and the bit line BL. The gate 16 may include a gate insulating layer 12 and a gate electrode 14. A first interlayer insulating layer 18 is formed on the substrate 10 on which the gate 16 is formed. A first plug 20 connected to the gate 16 is formed in the first interlayer insulating layer 18. The first plug 20 may be a metal plug. There may be other components such as but not limited to spacers (not illustrated).

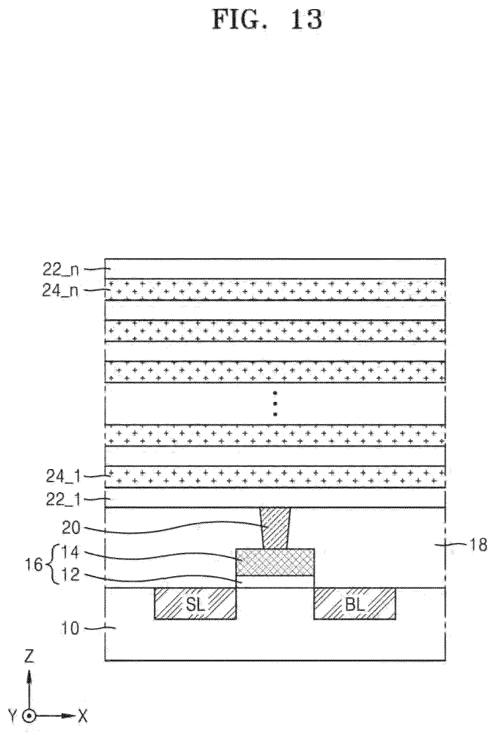

Referring to FIG. 13, the lower insulating layers 22_1 to 22_n (n is a positive integer) and the lower sacrificial layers 24_1 to 24_n, (n is a positive integer) are alternately stacked a plurality of times on the first plug 20 and the first interlayer insulating layer 18. The lower insulating layers 22_1 to 22_n and the lower sacrificial layers 24_1 to 24_n may be formed through a chemical vapor deposition (CVD) and/or an atomic layer deposition (ALD) process. A thickness of each of the lower insulating layers 22_1 to 22_n may be the same as each other, or at least one may be different than another. A thickness of each of the lower sacrificial layers 24_1 to 24_n may be the same as each other, or at least one may different than another.

The lower insulating layers 22_1 to 22_n may be made of a material having an etch selectivity compared to the lower sacrificial layers 24_1 to 24_n. The lower sacrificial layers 24_1 to 24_n may include a material that may be more easily removed through a wet etching process. For example, the lower insulating layers 22_1 to 22_n may include silicon oxide and may or may not include silicon nitride, and the lower sacrificial layers 24_1 to 24_n may include silicon nitride and may or may not include silicon oxide.

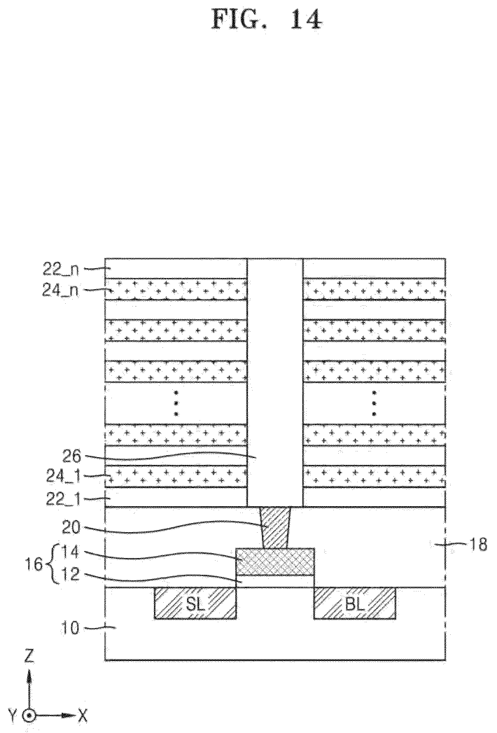

Referring to FIG. 14, a first channel hole 26 is formed through the lower insulating layers 22_1 to 22_n and the lower sacrificial layers 24_1 to 24_n. The first channel hole 26 is formed by selectively etching, e.g., anisotropically etching, the lower insulating layers 22_1 to 22_n and the lower sacrificial layers 24_1 to 24_n through a photolithography process. The first channel hole 26 may expose an upper surface of the first plug 20 and one side surfaces of the lower insulating layers 22_1 to 22_n and the lower sacrificial layers 24_1 to 24_n.

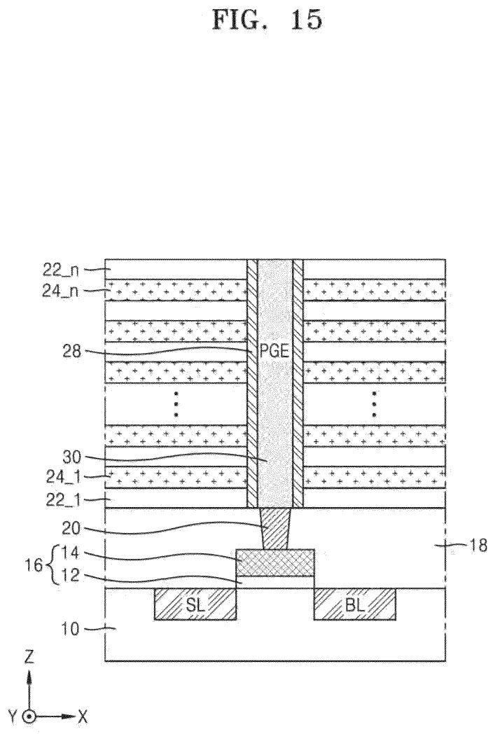

Referring to FIG. 15, a first dielectric layer 28 is formed on the inner wall of the first channel hole 26 in FIG. 14. The first dielectric layer 28 may be formed by forming a first dielectric material layer inside the first channel hole 26 and on the uppermost lower insulating layer 22_n and then etching back and/or polishing the first dielectric material layer.

Accordingly, the first dielectric layer 28 is not formed on the upper surface of the first plug 20 and the uppermost lower insulating layer 22_n.

The first dielectric layer 28 may be formed on one sides of the lower insulating layers 22_1 to 22_n and the lower sacrificial layers 24_1 to 24_n. The first dielectric layer 28 may be formed of a ferroelectric layer and/or an antiferroelectric layer.

Subsequently, a pillar gate electrode 30 is formed to fill the first channel hole 26 in FIG. 14 on the first dielectric layer 28 inside the first channel hole 26 in FIG. 14. The pillar gate electrode 30 may correspond to the pillar gate electrode PGE of FIGS. 2 to 4. The pillar gate electrode 30 may be formed by etching back and/or polishing the uppermost lower insulating layer 22_n as an etch stop point after forming a metal material layer on the inside of the first channel hole 26 in FIG. 14 and on the uppermost lower insulating layer 22_n.

Accordingly, the first dielectric layer 28 may be disposed to surround the pillar gate electrodes PGE 30. In cross-sectional view, the first dielectric layer 28 may be positioned on both sides of the pillar gate electrodes PGE 30.

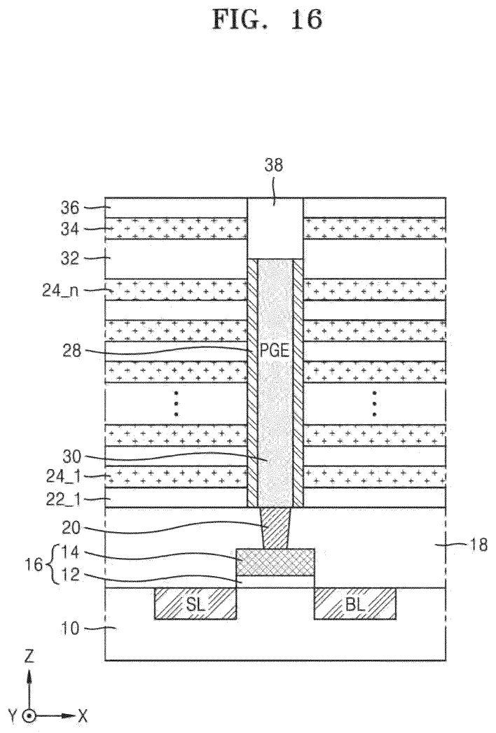

Referring to FIG. 16, after forming the first upper insulating layer 32, the upper sacrificial layer 34, and the second upper insulating layer 36 on the uppermost lower insulating layer 22_n, a second channel hole 38 is formed in the first upper insulating layer 32, the upper sacrificial layer 34, and the second upper insulating layer 36.

The second channel hole 38 may be formed to expose upper surfaces of the pillar gate electrode 30 and the first dielectric layer 28, and one side surfaces of the first upper insulating layer 32, the upper sacrificial layer 34, and the second upper insulating layer 36. The second channel hole 38 may be formed to communicate with the first channel hole 26 in FIG. 14.

The first and second upper insulating layers 32 and 36 may be made of a material having an etch selectivity compared to the upper sacrificial layer 34. The upper sacrificial layer 34 may include a material that may be more easily removed through a wet etching process. For example, the first and second upper insulating layers 32 and 36 may include silicon oxide and may or may not include silicon nitride, and the upper sacrificial layer 34 may include silicon nitride and may or may not include silicon oxide.

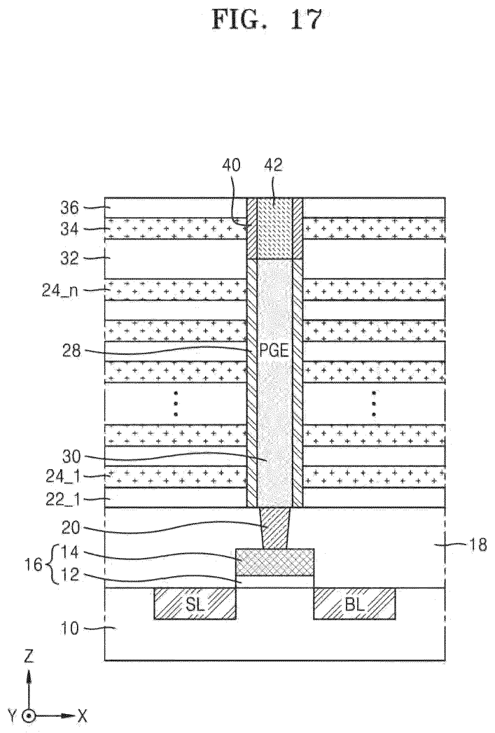

Referring to FIG. 17, a second dielectric layer 40 is formed on the inner wall of the second channel hole 36 in FIG. 16. After forming a second dielectric material layer on the inside of the second channel hole 36 in FIG. 16 and on the second upper insulating layer 36, the second dielectric layer 40 may be formed by etching back the second dielectric material layer. Accordingly, the second dielectric layer 40 is not formed on the upper surface of the pillar gate electrode 30.

The second dielectric layer 40 may be formed on one sides of the first and second upper insulating layers 32 and 36 and the upper sacrificial layer 34. The second dielectric layer 40 may be formed of a silicon oxide layer.

Subsequently, a channel layer 42 is formed to fill the second channel hole 38 in FIG. 16 on the pillar gate electrode 30 inside the second channel hole 38 in FIG. 16. After forming a channel material layer on the inside of the second channel hole (38 in FIG. 16) and on the second upper insulating layer 36, the channel layer 42 may be formed by etching back the second upper insulating layer 36 as an etch stop point.

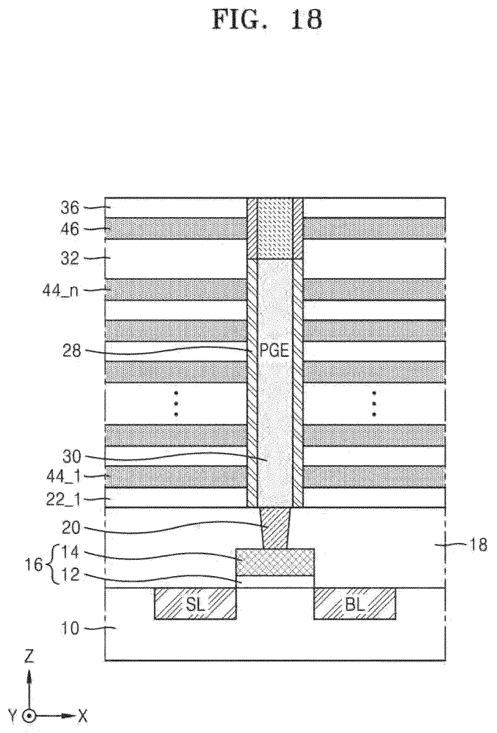

Referring to FIG. 18, the lower sacrificial layers 24_1 to 24_n and the upper sacrificial layer 34 are replaced with horizontal word lines WL1 to WLn and a string selection line SSL, respectively. After removing the lower sacrificial layers 24_1 to 24_n and the upper sacrificial layer 34, horizontal word lines WL1 to WLn and a string selection line SSL are formed in the removed portion.

Accordingly, the first dielectric layer 28 may be positioned between the pillar gate electrodes PGE 30 and the horizontal word lines WL1 to WLn. As described above, a variable capacitor VCA in FIG. 3 may be formed by the first dielectric layer 28 between the pillar gate electrode 30 and the horizontal word lines WL1 to WLn. In addition, a selection transistor SETR including a string selection line SSL, a second dielectric layer 40, and a channel layer 42 may be formed.

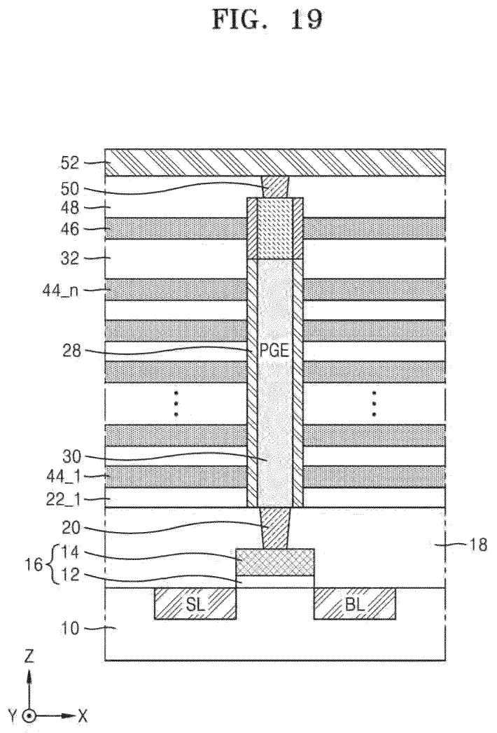

Referring to FIG. 19, after forming the second interlayer insulating layer 48 on the second upper insulating layer 36, the second dielectric layer 40, and the channel layer 42, a second plug 50 connected to the channel layer 42 is formed on the second interlayer insulating layer 48.

Subsequently, by forming a control line 52 connected to the second plug 50 on the second plug 50 and the second interlayer insulating layer 48, the unit cell UC1 of the three dimensional non-volatile memory device EM1 in FIG. 1 may be manufactured.

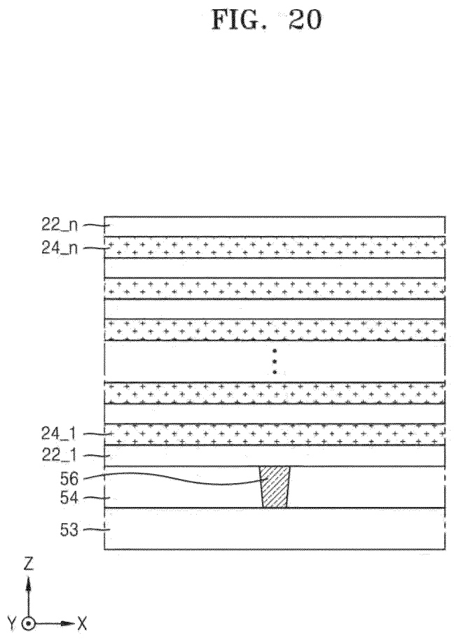

FIGS. 20 to 26 are cross-sectional views illustrating a method of manufacturing a unit cell of a three dimensional non-volatile memory device according to some example embodiments.

Specifically, FIGS. 20 to 26 are for explaining a manufacturing method of a modified example of the unit cell UC1 of FIGS. 2 to 4 of the three dimensional non-volatile memory device EM1 of FIG. 1. FIGS. 20 to 26 may include connecting the storage transistor STTR to the pillar gate electrode using the first plug 20 and the third plug 72 compared to FIGS. 12 to 19.

Compared with FIGS. 12 to 19, FIGS. 20 to 26 may include bonding and/or connecting the first plug 20 to the third plug 72 using a bonding method such as wafer bonding method. In FIGS. 20 to 26, the same or similar reference numerals as those in FIGS. 12 to 19 describe the same or similar contents. In FIGS. 20 to 26, members identical to or similar to those in FIGS. 12 to 19 are simply described or omitted.

Referring to FIG. 20, a second interlayer insulating layer 54 is formed on the first substrate 53. The second interlayer insulating layer 54 corresponds to the second interlayer insulating layer 48 of FIG. 19. A second plug 56 is formed in the second interlayer insulating layer 54. The second plug 56 corresponds to the second plug 50 of FIG. 19.

The lower insulating layers 22_1 to 22_n (n is a positive integer) and the lower sacrificial layers 24_1 to 24_n (n is a positive integer) are alternately stacked a plurality of times on the second interlayer insulating layer 54 and the second plug 56. The lower insulating layers 22_1 to 22_n and the lower sacrificial layers 24_1 to 24_n may be formed through a chemical vapor deposition (CVD) process and/or an atomic layer deposition (ALD) process.

The lower insulating layers 22_1 to 22_n may be made of a material having an etch selectivity compared to the lower sacrificial layers 24_1 to 24_n. The lower sacrificial layers 24_1 to 24_n may include a material that may be easily removed through a wet etching process. For example, the lower insulating layers 22_1 to 22_n may include silicon oxide, and the lower sacrificial layers 24_1 to 24_n may include silicon nitride.

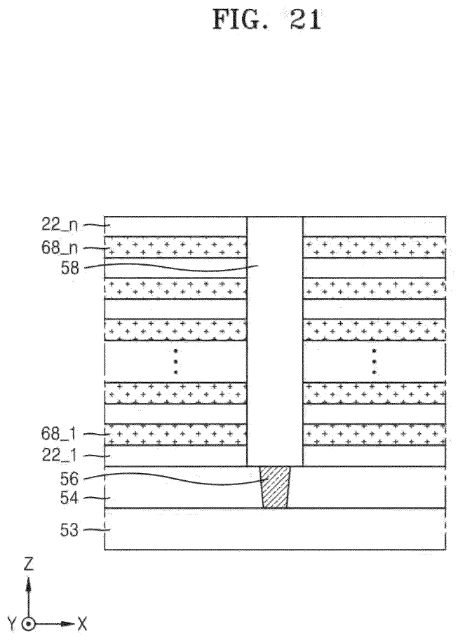

Referring to FIG. 21, a first channel hole 58 is formed through the lower insulating layers 22_1 to 22_n and the lower sacrificial layers 24_1 to 24_n. The first channel hole 58 is formed by selectively etching the lower insulating layers 22_1 to 22_n and the lower sacrificial layers 24_1 to 24_n through a photolithography process.

The first channel hole 58 may expose an upper surface of the second plug 56 and one side surfaces of the lower insulating layers 22_1 to 22_n and the lower sacrificial layers 24_1 to 24_n. The first channel hole 58 may correspond to the first channel hole 26 of FIG. 14.

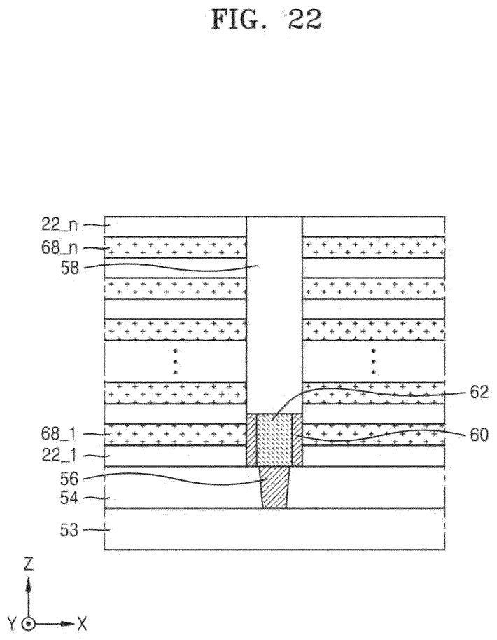

Referring to FIG. 22, a second dielectric layer 60 is formed on a portion of the inner wall of the first channel hole 58. The second dielectric layer 60 may be formed by forming a second dielectric material layer inside the first channel hole 58 and on the uppermost lower insulating layer 22_n and then etching back the second dielectric material layer.

Accordingly, the second dielectric layer 60 is not formed on the upper surface of the second plug 58 and the uppermost lower insulating layer 22_n. The second dielectric layer 60 may be formed on one side of the lower insulating layer 22_1 and the lower sacrificial layer 24_1. The second dielectric layer 60 may be formed of a silicon oxide layer.

Subsequently, a channel layer 62 is formed to partially fill the first channel hole 58 on the second dielectric layer 60 inside the first channel hole 58. The channel layer 62 may be formed by forming a channel material layer on an inner portion of the first channel hole 58 and on the uppermost lower insulating layer 22_n and then performing an etch-back process.

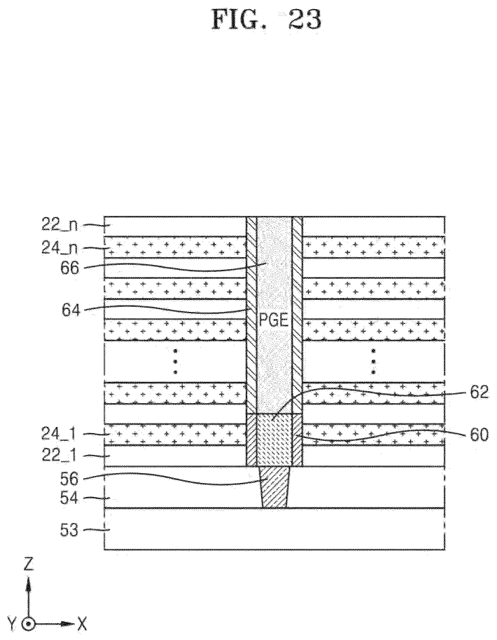

Referring to FIG. 23, a first dielectric layer 64 is formed on the inner wall of the first channel hole 58 on the second dielectric layer 60 and the channel layer 62. The first dielectric layer 64 may be formed on one side of the lower insulating layers 22_2 to 22_n and the lower sacrificial layers 24_2 to 24_n. The first dielectric layer 28 may be formed of a ferroelectric layer or an antiferroelectric layer.

A pillar gate electrode 66 is formed to fill the first channel hole 58 in FIG. 22 on the channel layer 62 inside the first channel hole 58 in FIG. 22. The pillar gate electrode 66 may correspond to the pillar gate electrode PGE of FIGS. 2 to 4. The pillar gate electrode 66 may be formed by etching back the uppermost lower insulating layer 22_n as an etch stop point after forming a metal material layer on the inside of the first channel hole 58 in FIG. 22 and on the uppermost lower insulating layer 22_n.

Accordingly, the first dielectric layer 64 may be disposed to surround the pillar gate electrodes 66. In cross-sectional view, the first dielectric layer 64 may be positioned on both sides of the pillar gate electrodes 66.

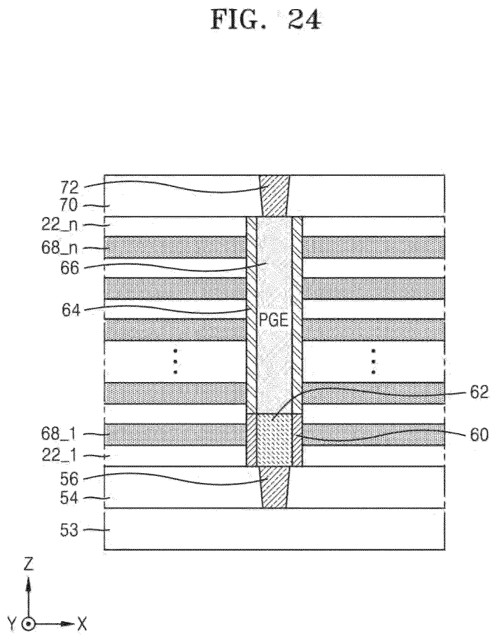

Referring to FIG. 24, the lower sacrificial layers 24_1 to 24_n are replaced with a string selection line SSL and horizontal word lines WL1 to WLn. After removing the lower sacrificial layers 24_1 to 24_n, a string selection line SSL and horizontal word lines WL1 to WLn are formed in the removed portion.

Accordingly, the first dielectric layer 64 may be positioned between the pillar gate electrodes 66 and the horizontal word lines WL1 to WLn. As described above, a variable capacitor VCA in FIG. 3 may be formed by the first dielectric layer 64 between the pillar gate electrode 66 and the horizontal word lines WL1 to WLn. In addition, a selection transistor SETR including a string selection line SSL, a second dielectric layer 60, and a channel layer 62 may be formed.

Subsequently, after forming the third interlayer insulating layer 70 on the uppermost lower insulating layer 22_n, the first dielectric layer, and the pillar gate electrode, a third plug 72 connected to the pillar gate electrode is formed in the third interlayer insulating layer 70.

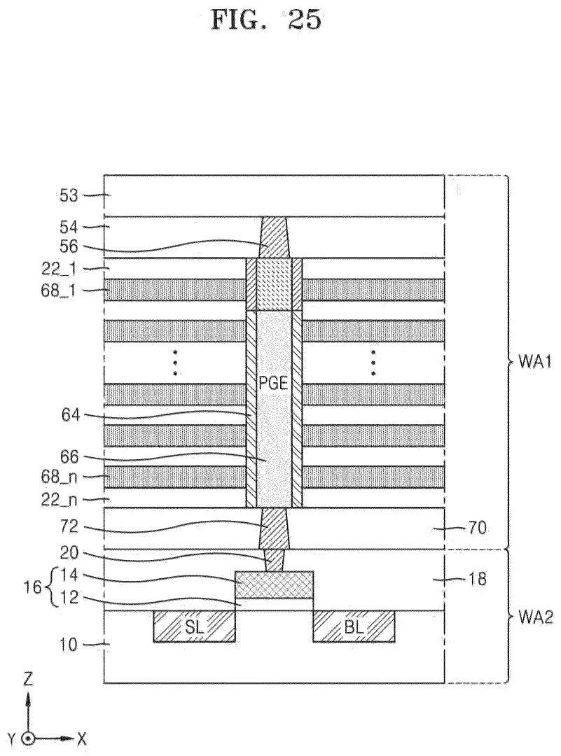

Referring to FIG. 25, the structure of FIG. 24 is inverted. In this way, a first substrate structure WA1 including a string selection line SSL, horizontal word lines, a pillar gate electrode, and a third plug may be formed.

Next, a storage transistor STTR is formed on the second substrate 10. The storage transistor STTR may include a source line SL and a bit line BL formed apart from each other on the first substrate 10. The source line SL and the bit line BL may be a source region and a drain region respectively formed on the substrate 10.

A gate 16 is formed on the first substrate 10 between the source line SL and the bit line BL. The gate 16 may include a gate insulating layer 12 and a gate electrode 14. A first interlayer insulating layer 18 is formed on the substrate 10 on which the gate 16 is formed. A first plug 20 connected to the gate 16 is formed in the first interlayer insulating layer 18. The first plug 20 may be a metal plug. In this way, a second wafer structure WA2 having the storage transistor STTR, the first plug 20, and the first interlayer insulating layer 18 formed on the first substrate 10 may be formed.

Next, the third plug and the third interlayer insulating layer of the first substrate structure WA1 may be bonded to the first plug and the first interlayer insulating layer of the second substrate structure, for example, hybrid bonding. Through this, the first plug of the second substrate structure and the third plug of the first substrate structure may be electrically connected to each other.

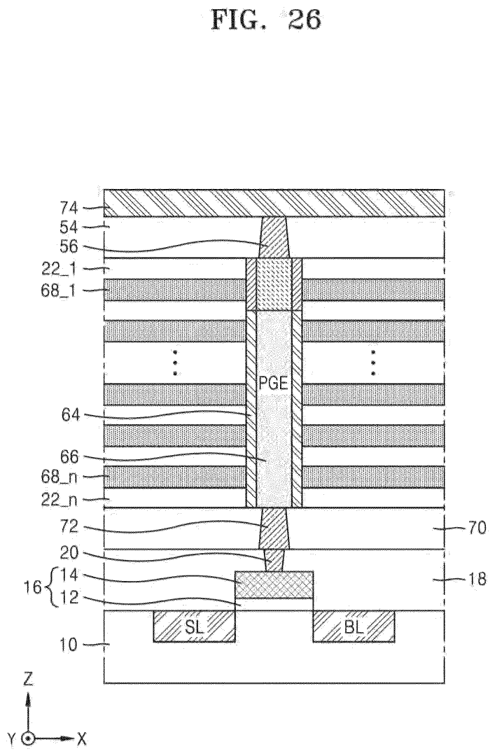

Referring to FIG. 26, the first substrate 53 of the first substrate structure is removed by etching back. In this way, the second plug and the second interlayer insulating layer are exposed. Subsequently, by forming a control line 74 connected to the second plug 56 on the second plug 56 and the second interlayer insulating layer 54, the unit cell UC1 of the three dimensional non-volatile memory device EM1 in FIG. 1 may be manufactured.

While inventive concepts have been particularly shown and described with reference to embodiments thereof, it will be understood that various changes in form and details may be made therein without departing from the spirit and scope of the following claims. Furthermore, example embodiments are not necessarily mutually exclusive with one another. For example, some example embodiments may include one or more features described with reference to one or more figures and may also include one or more other features described with reference to one or more other figures.

What is claimed is:

1. A three-dimensional non-volatile memory device comprising:
a plurality of horizontal word lines spaced apart from each other in a vertical direction;
a pillar gate electrode buried in a first channel hole that passes through the horizontal word lines in the vertical direction;
a first dielectric layer between the pillar gate electrode and the horizontal word lines in a cross section, wherein the pillar gate electrode, the first dielectric layer, and the horizontal word lines correspond to memory cells including a plurality of variable capacitors spaced apart from each other in a vertical direction;
a selection transistor on the pillar gate electrode and the horizontal word lines and connected to one end of the pillar gate electrode; and
a storage transistor under the pillar gate electrode and the horizontal word lines and connected to another end of the pillar gate electrode.

2. The three-dimensional non-volatile memory device of claim 1, wherein one side surface of the first dielectric layer planarly surrounds the pillar gate electrode, and another side surface of the first dielectric layer is planarly in contact with the horizontal word lines.

3. The three-dimensional non-volatile memory device of claim 1, wherein the first dielectric layer includes at least one of a ferroelectric layer or an antiferroelectric layer.

4. The three-dimensional non-volatile memory device of claim 1, wherein the another end of the pillar gate electrode is connected to a gate of the storage transistor.

5. The three-dimensional non-volatile memory device of claim 1, wherein the storage transistor is connected to a bit line.

6. The three-dimensional non-volatile memory device of claim 1, wherein the storage transistor is connected to a source line.

7. The three-dimensional non-volatile memory device of claim 1, wherein the selection transistor is connected to a control line.

8. The three-dimensional non-volatile memory device of claim 1, wherein
the selection transistor comprises: a string selection line apart in the vertical direction from an uppermost horizontal word line among the horizontal word lines;
a channel layer connected to one end of the pillar gate electrode; and
a second dielectric layer disposed between the channel layer and the string selection line.

9. The three-dimensional non-volatile memory device of claim 8, wherein the channel layer of the selection transistor is connected to a control line.

10. A three-dimensional non-volatile memory device comprising:
a plurality of horizontal word lines spaced apart from each other in a vertical direction;
a pillar gate electrode buried in a first channel hole that passes through the horizontal word lines in the vertical direction;
a first dielectric layer between the pillar gate electrode and the horizontal word lines in a cross section, wherein the pillar gate electrode, the first dielectric layer, and the horizontal word lines correspond to memory cells including a plurality of variable capacitors spaced apart from each other in a vertical direction;
a string selection line spaced apart in the vertical direction from an uppermost horizontal word line among the horizontal word lines;
a channel layer buried in a second channel hole that passes through the string selection line in the vertical direction and is connected to one end of the pillar gate electrode;
a second dielectric layer between the channel layer and the string selection line; and
a storage transistor connected to another end of the pillar gate electrode.

11. The three-dimensional non-volatile memory device of claim 10, wherein the string selection line, the channel layer and the second dielectric layer are included in a selection transistor.

12. The three-dimensional non-volatile memory device of claim 11, wherein the channel layer of the selection transistor is connected to a control line.

13. The three-dimensional non-volatile memory device of claim 11, wherein the storage transistor is connected to a source line.

14. The three-dimensional non-volatile memory device of claim 11, wherein the storage transistor is connected to a bit line.

15. The three-dimensional non-volatile memory device of claim 11, wherein one side surface of the first dielectric layer planarly surrounds the pillar gate electrode, and another side surface of the first dielectric layer is planarly in contact with the horizontal word lines.

16. The three-dimensional non-volatile memory device of claim 11, wherein the first dielectric layer includes at least one of a ferroelectric layer or an antiferroelectric layer.

17. A three-dimensional non-volatile memory device comprising:
a plurality of horizontal word lines spaced apart from each other in a vertical direction;
a pillar gate electrode buried in a first channel hole that passes through the horizontal word lines in the vertical direction;
a first dielectric layer between the pillar gate electrode and the horizontal word lines in a cross section, wherein the pillar gate electrode, the first dielectric layer, and the horizontal word lines correspond to memory cells including a plurality of variable capacitors spaced apart from each other in a vertical direction;
a selection transistor on the pillar gate electrode and the horizontal word lines and connected to one end of the pillar gate electrode, wherein the selection transistor comprises a string selection line apart in the vertical direction from an uppermost horizontal word line among the horizontal word lines, a channel layer connected to one end of the pillar gate electrode, and a second dielectric layer between the channel layer and the string selection line;
a storage transistor below the pillar gate electrode and the horizontal word lines and connected to another end of the pillar gate electrode; and
a control transistor below the pillar gate electrode and the horizontal word lines and connected to the storage transistor.

18. The three-dimensional non-volatile memory device of claim 17, wherein the control transistor is connected in series with the storage transistor.

19. The three-dimensional non-volatile memory device of claim 17, wherein the another end of the pillar gate electrode is connected to a gate of the storage transistor.

20. The three-dimensional non-volatile memory device of claim 17, wherein one side surface of the first dielectric layer surrounds the pillar gate electrode in a plan view, and another side surface of the first dielectric layer is planarly in contact with the horizontal word lines.
